(19) United States
(12) Patent Application Publication
(10) Pub. No.: US 2008/0237687 A1
(43) Pub. Date: Oct. 2, 2008

(54) Flash memory device

(75) Inventors: Sun-il Kim, Yongin-si (KR); Young-gu Jin, Yongin-si (KR); I-hun Song, Yongin-si (KR); Young-soo Park, Yongin-si (KR); Dong-hun Kang, Yongin-si (KR); Chang-jung Kim, Yongin-si (KR); Jae-chul Park, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/898,037

(22) Filed: Sep. 7, 2007

(30) Foreign Application Priority Data
Mar. 29, 2007 (KR) 10-2007-0031087

(51) Int. Cl. H01L 29/788

(52) U.S. Cl. 257/316

(57) ABSTRACT

Provided is a flash memory device including a gate structure on a substrate. The flash memory device includes a charge supply layer including a ZnO based material formed between a substrate and a gate structure or formed on the gate structure. Accordingly, the flash memory device can be formed to be of a bottom gate type or of a top gate type by including the charge supply layer. Also, the flash memory device may be realized to be any of a charge trap type and a floating gate type.

### CROSS-REFERENCE TO RELATED PATENT APPLICATION

This application claims the benefit of Korean Patent Application No. 10-2007-0031087, filed on Mar. 29, 2007 in the Korean Intellectual Property Office, the disclosure of which is incorporated herein in its entirety by reference.

### BACKGROUND OF THE INVENTION

1. Field of the Invention

The present invention relates to a flash memory device, and more particularly, to a flash memory device which can be formed without requiring a doping process for forming a source/drain region and in which a stack structure can be easily realized.

2. Description of the Related Art

A non-volatile memory device in the field of semiconductor memory devices is a storage device in which stored data is not lost and is stored even when the power supply turns off.

The structure of a memory cell constituting a non-volatile semiconductor memory device varies according to the field in which a semiconductor memory device is used.

In the case of a NAND (not AND) type flash memory device, which is one type of high capacity non-volatile semiconductor memory device, a gate of a transistor includes a floating gate in which charges, that is, data, is stored, and a control gate which controls the floating gate, which are sequentially stacked.

In such a flash memory device, in order to satisfy the demand of expanding the memory capacity, the size of memory cells is being rapidly reduced. Also, according to the reduction in the size of the memory cell, it is required to reduce efficiently the height of the floating gate in a vertical direction.

As with efficiently reducing the height of the memory cell in a vertical direction, to maintain the memory characteristics of the memory cell such as the retention characteristics of maintaining stored data for a long period of time, a charge trap flash (CTF) memory device which uses a charge trap layer such as a silicon nitride (Si₃N₄) layer instead of a floating gate as a charge storing means is being developed.

A flash memory device can be classified into structures having a floating gate and structures having a charge trap layer. A general flash memory device denotes a structure having a floating gate, and hereinafter, in order to distinguish the flash memory device of the structure having a floating gate from the charge trap type flash memory device, the flash memory device of the structure having a floating gate will be referred to as a floating gate type flash memory device.

In general, in the floating gate type flash memory device or the charge trap type flash memory device including a charge trap layer instead of a floating gate, a single crystal silicon is used as a charge supply layer.

However, when silicon is used for a charge supply layer, channel doping, source/drain n-doping, or well doping are required.

Also, when silicon is used as a charge supply layer, it is difficult to form a stack structure for realizing a highly integrated memory device. This is because a high temperature process in the region of about 1000° C. is required to deposit silicon, and it is substantially difficult to form a multi-layer stack structure by silicon deposition. Accordingly, in order to realize a memory having a stack structure, polysilicon needs to be used or a wafer bonding method needs to be applied. However, these methods are expensive and difficult to apply in practice.

### SUMMARY OF THE INVENTION

The present invention provides a flash memory device which can be formed without requiring a doping process for forming a source/drain region and in which a stack structure can be easily realized, and a method of manufacturing the flash memory device.

According to an aspect of the present invention, there is provided a flash memory device comprising a gate structure on a substrate, the flash memory device comprising: a charge supply layer including a ZnO based material formed between the substrate and the gate structure or formed on the gate structure.

The charge supply layer may be formed of a material including ZnO or GaInZnO.

The charge supply layer may be formed of a material including a(In₂O₃).b(Ga₂O₃).c(ZnO) (where, a, b, and c are real numbers satisfying the condition: a≧0, b≧0, c>0).

The charge supply layer may be formed of a material including a(In₂O₃).b(Ga₂O₃).c(ZnO) (where a, b, and c are real numbers satisfying the condition: a≧1, b≧1, 0<c≦1).

The flash memory device may further comprise a buffer layer between the substrate and the charge supply layer.

The buffer layer may be formed to include one selected from the group consisting of a p-type semiconductor material, an intrinsic semiconductor, NiO, CuAlO₂, SrCu₂O₂, LaCuOS, SiO₂, and SiNₓ.

The flash memory device may further comprise a source/drain region formed in the charge supply layer to be connected to the gate structure.

The source/drain region may be formed by plasma processing.

The flash memory device may be of a top-gate type in which the gate structure is formed on the charge supply layer, and the gate structure may include a tunneling insulating layer, a charge trap layer, a blocking insulating layer, and a control gate layer sequentially stacked on the charge supply layer.

The flash memory device may be of a top-gate type in which the gate structure is formed on the charge supply layer, and the gate structure may include a tunneling insulating layer, a floating gate layer, an insulating layer between gates, and a control gate layer sequentially stacked on the charge supply layer.

The flash memory device may be of a bottom gate type in which the gate structure is formed on the substrate and the charge supply layer is formed on the gate structure, wherein the gate structure includes a control gate layer, a blocking insulating layer, a charge trap layer, and a tunneling insulating layer sequentially stacked on the substrate, and the charge supply layer is formed on the tunneling insulating layer.

The flash memory device may be of a bottom gate type in which the gate structure is formed on the substrate and the charge supply layer is formed on the gate structure, wherein the gate structure includes a control gate layer, a blocking insulating layer, a floating gate layer, and a tunneling insulating layer sequentially stacked on the substrate, and the charge supply layer is formed on the tunneling insulating layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view of a flash memory device according to an embodiment of the present invention;

FIGS. 2 and 3 show the results of a tests when a charge supply layer is formed of GaInZnO in the flash memory device of FIG. 1;

FIGS. 4 through 8 are schematic views of a flash memory device according to embodiments of the present invention;

FIGS. 9A through 9D illustrate a method of manufacturing a top gate type flash memory device according to the present invention; and

FIGS. 10A through 10E illustrate a method of manufacturing a bottom gate type flash memory device according to the present invention.

### DETAILED DESCRIPTION OF THE INVENTION

The present invention will now be described more fully with reference to the accompanying drawings, in which exemplary embodiments of the invention are shown.

A flash memory device according to an embodiment of the present invention may be of a floating gate type or a charge trap layer type. That is, the flash memory device according to the current embodiment of the present invention includes a floating gate type flash memory device and a charge trap type flash memory device.

The floating gate type flash memory device has a gate structure including a tunneling insulating layer, a floating gate layer, an inter-gate insulating layer, and a control gate layer. The charge trap type flash memory device has a gate structure including a tunneling insulating layer, a charge trap layer, a blocking insulating layer, and a control gate layer.

The flash memory device according to the current embodiment of the present invention includes an additional layer for supplying charges. This charge supply layer may be formed of a ZnO based material having greater charge mobility than amorphous silicon, for example, a material including ZnO or ZnO doped with Ga and In, that is, a material including GaInZnO. When the flash memory device includes such a charge supply layer, as will be described later, additional doping process for forming a channel can be omitted, and a source/drain region can be formed by not using an n-doping process but by using another method such as plasma processing, thereby simplifying the manufacturing process of the flash memory device.

Also, as the charge supply layer including a ZnO based material is included in the flash memory device, a stack structure for realizing a highly integrated memory device can be easily formed on a substrate.

Also, as the additional charge supply layer is included in the flash memory device, the flash memory device according to the current embodiment of the present invention may be any of a bottom gate type device and a top gate type device.

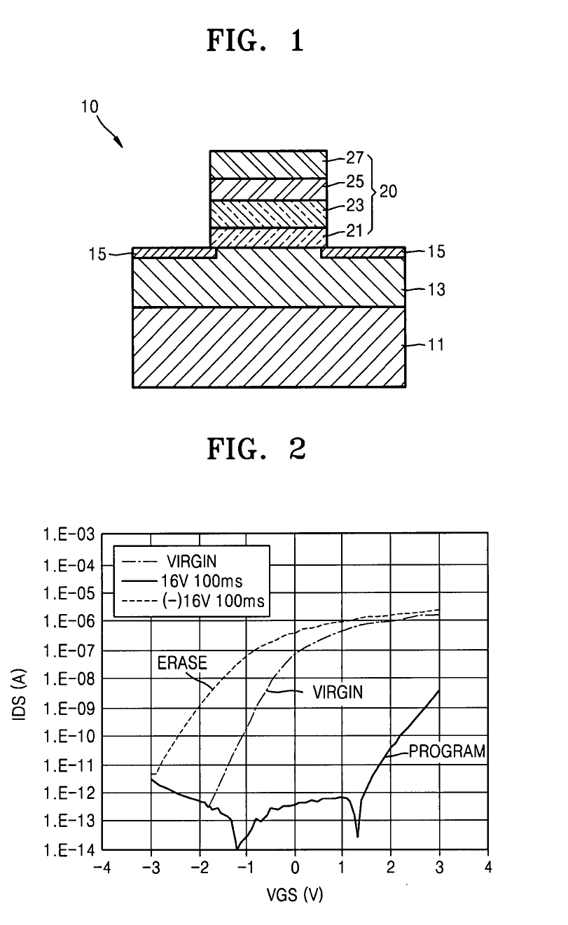

FIG. 1 is a schematic view of a flash memory device 10 according to an embodiment of the present invention.

Referring to FIG. 1, the flash memory device 10 is a top gate type charge trap flash (CTF) memory device and includes a substrate 11, a charge supply layer 13 formed on the substrate 11, and a gate structure 20 formed on the charge supply layer 13.

Since the substrate 11 is not used as a source of charges in the flash memory device 10, the material forming the substrate 11 is not limited and may be various. For example, the substrate 11 may be one of a silicon substrate, a glass substrate, and a plastic substrate.

The charge supply layer 13 in the flash memory device 10 may be formed of a ZnO based compound semiconductor, for example, a compound semiconductor material including ZnO or ZnO doped with Ga and In, that is, a compound semiconductor material including GaInZnO (GIZO).

In detail, the charge supply layer 13 may be formed of a material including a(In₂O₃).b(Ga₂O₃).c(ZnO). Here, a, b, and c may be real numbers satisfying the condition a≧0, b≧0, c>0, preferably, a≧1, b≧1, 0<c≦1.

The charge supply layer 13 formed of a material including ZnO or GaInZnO is an n-type semiconductor layer, and the density of carriers therein can be adjusted according to the deposition condition. For example, the density of carriers can be adjusted by varying the composition of GaInZnO or ZnO by adjusting the amount of Ga and In which are doped on the ZnO or the amount of oxygen used during ZnO sputtering.

Also, a threshold voltage (Vth) can be adjusted by varying the composition of GaInZnO or ZnO by adjusting the deposition conditions of GaInZnO or ZnO.

Since the charge mobility of ZnO based materials such as GaInZnO or ZnO is greater than amorphous silicon, when a ZnO based material is used to form a channel, additional doping processes for forming a channel are not required. Also, a source/drain region 15 can be formed by not using a dopant doping process which requires a high temperature process but instead by using a plasma processing method. The source/drain region 15 is formed on the charge supply layer 13 to contact both ends of the gate structure 20. The charge supply layer 13 between the source/drain region 15 and under the gate structure 20 is used as a channel region.

Since a ZnO based compound semiconductor material such as GaInZnO or ZnO still keeps the characteristics of a semiconductor in an amorphous state, it is also advantageous for forming a multi-layer stack structure.

The charge supply layer 13 may be formed to a proper thickness so that the channel region is not affected by a back bias voltage when a back bias voltage (Vbb) is applied to the flash memory device 10.

The charge supply layer 13 can also be formed to a thin thickness such that a current flows through the entire charge supply layer 13. Then flash memory devices can be connected in a NAND structure without the source/drain region 15, and thus the source/drain region 15 in FIG. 1 may not be needed.

The gate structure 20 includes a tunneling insulating layer 21 formed on the charge supply layer 13, a charge trap layer 23 formed on the tunneling insulating layer 21, a blocking insulating layer 25 formed on the charge trap layer 23, and a control gate layer 27 formed on the blocking insulating layer 25.

The tunneling insulating layer 21 is for charge tunneling and is formed on the charge supply layer 13. The source/drain region 15 is formed on the charge supply layer 13 to contact the tunneling insulating layer 21. The tunneling insulating layer 21 may be a tunneling oxide layer formed of, for example, SiO₂, or various high-k oxides or an oxide formed of a combination of these.

Alternatively, the tunneling insulating layer 21 may be a silicon nitride layer formed of, for example, Si₃N₄.

Alternatively, the tunneling insulating layer 21 may be a double-layer structure formed of a silicon nitride layer and an oxide layer.

As described above, the tunneling insulating layer 21 may be a single-layer structure formed of an oxide or a nitride or a multi-layer structure formed of materials having different energy band gaps. Besides this, the tunneling insulating layer 21 may be formed of various materials in various structures.

In the charge trap layer 23, data is stored by charge trapping. The charge trap layer 23 may be formed to include one of polysilicon, nitride, high-k dielectric material, and nanodots.

For example, the charge trap layer 23 may be formed of a nitride such as Si₃N₄ or a high-k oxide such as SiO₂, HfO₂, ZrO₂, Al₂O₃, HfSiON, HfON or HfAlO.

Also, the charge trap layer 23 may include a plurality of nanodots that are discontinuously arranged as a charge trap site. The nanodots may be formed of nano crystals.

The charge trap layer 23 may be formed of various materials and in various structures.

The blocking insulating layer 25 is formed to block charges from passing upward from the charge trap layer 23, that is, toward the control gate electrode 27 and may be formed of an oxide layer.

The blocking insulating layer 25 may be formed of SiO₂ or a high-k material having greater dielectric constant than the tunneling insulating layer 21, for example, Si₃N₄, Al₂O₃, HfO₂, Ta₂O₅ or ZrO₂. The blocking insulating layer 25 may be formed of a multi-layer structure. For example, the blocking insulating layer 25 may be formed of two layers or more, including an insulating layer formed of an insulating material that is usually used, such as SiO₂ and a high-k dielectric layer formed of a material having a greater dielectric constant than the tunneling insulating layer 21.

The control gate layer 27 may be formed of a metal layer. For example, the control gate layer 27 may be formed of a metal layer such as Al, Ru, TaN, and so on. Also, the control gate layer 27 may be formed of a silicide such as NiSi.

As described above, in the flash memory device 10 according to the current embodiment of the present invention, the threshold voltage (Vth) of the flash memory device 10 can be adjusted by varying the deposition conditions to form the charge supply layer 13, for example, the composition of GaInZnO or ZnO, by adjusting the amount of Ga and In which are doped on the ZnO or the amount of oxygen used during ZnO sputtering. Also, the density of carriers therein can be adjusted, and thus no doping processes for forming the source/drain region 15 are required, thereby simplifying the manufacturing process. The source/drain region 15 can be formed using a plasma processing method and the charge supply layer 13 functions as a channel and no doping processes for forming a channel are required.

Also, as the charge supply layer 13 is included, no single crystal substrate is needed and a stack structure for realizing a highly integrated memory device can be easily formed on a substrate, and thus a multi-stack structure can be easily realized.

That is, in order to deposit silicon, a high temperature process, for example, at about 1000° C., is required, and thus, it is not feasible to form a multi-layer stack structure by silicon deposition. Accordingly, when silicon is used as the charge supply layer, expensive wafer bonding or polysilicon are used for forming a stack structure. However, these processes are expensive and difficult to apply practically.

On the other hand, according to the current embodiment of the present invention, when the charge supply layer 13, formed of a ZnO based material such as a material including ZnO or GaInZnO, is included, the charge supply layer 13 can be formed at a lower temperature than required for silicon, and thus the manufacturing cost is low and a stacked memory device can be easily realized. The charge supply layer 13 may be formed, for example, at 150 to 500° C., preferably at 250 to 400° C.

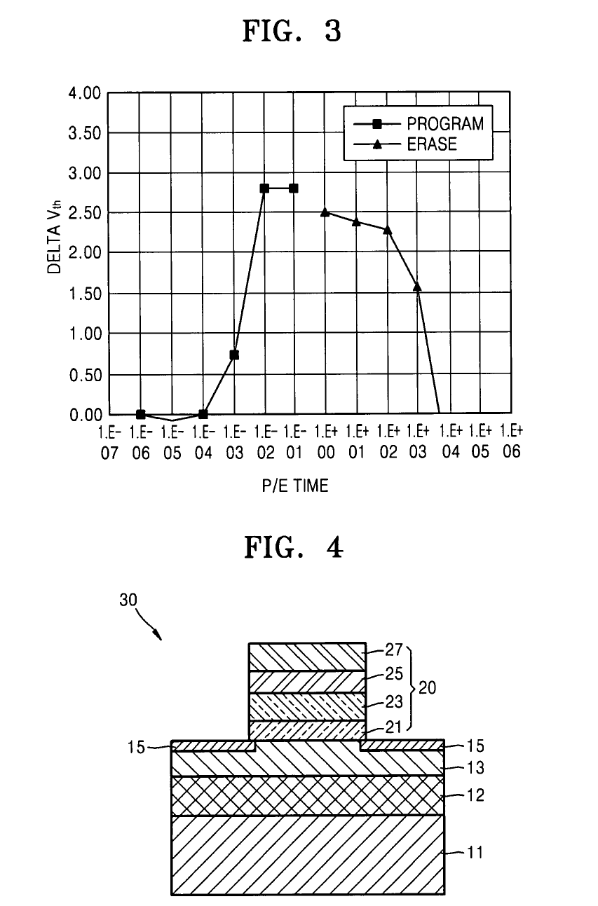

FIGS. 2 and 3 show the results of a tests demonstrating that the flash memory device of FIG. 1 includes a charge supply layer formed of GaInZnO.

FIG. 2 shows the test results obtained with respect to a sample when applying no electrical stress (virgin state) (Test 1), applying an electrical stress of +16 V at periods of 100 ms (Test 2), and applying an electrical stress of −16 V at periods of 100 ms (Test 3).

From the results of Tests 1, 2, 3, the variation of a current (Ids) flowing between a drain and a source with respect to voltage Vgs applied between a control gate electrode and a source is examined.

As can be seen from the result of Test 2, the threshold voltage when applying the electrical stress of +16 V at periods of 100 ms is increased by about 3.5 V from the threshold voltage of the sample when in the virgin state. This indicates that the flash memory device 10 has a programming characteristic.

As can be seen from the result of Test 3, the threshold voltage when applying the electrical stress of −16 V at periods of 100 ms is decreased by about 2 V compared to the threshold voltage of the sample when in the virgin state. This indicates the flash memory device 10 has an erasing characteristic.

In FIG. 3, the horizontal axis denotes the programming/erasing time, and the vertical axis denotes the variation ΔVth of the threshold voltage during programming and erasing. Referring to FIG. 3, the programming time showing sufficient variation of the threshold voltage Vth when programming using a positive voltage bias is shorter than the erasing time showing sufficient variation of the threshold voltage Vth when erasing using a negative voltage bias. In FIG. 3 a great threshold voltage variation is shown in the range of the programming time from about 1 ms to 0.1 s, and a great threshold voltage variation is shown in the range of the erasing time from about 1 s to 1000 s.

This indicates that the programming speed is higher than the erasing speed in the flash memory device according to the current embodiment of the present invention, satisfying the condition required for a standard flash memory device that the programming speed should be higher than the erasing speed.

FIGS. 2 and 3 do not show the result of testing the programming/erasing performance of the flash memory device according to the current embodiment but show that the programming and erasing operations are possible and that the programming speed is higher than the erasing speed in the flash memory device according to the current embodiment of the present invention.

As can be seen from the test results of FIGS. 2 and 3, a flash memory device including the charge supply layer 13 including a ZnO based material, for example, a material including GaInZnO, can be realized.

FIG. 4 is a schematic view of a flash memory device 30 according to another embodiment of the present invention, further including a buffer layer 12 in addition to the flash memory device 10 of FIG. 1. The buffer layer 12 is disposed between the substrate 11 and the charge supply layer 13.

The buffer layer 12 may be formed of a material having a smaller work function than a ZnO based material, for example, a material including ZnO or GaInZnO, such that barriers can be formed on a conduction band. The buffer layer 12 may be a p-type semiconductor or an intrinsic semiconductor material.

The buffer layer 12 may be formed of one selected from the group consisting of a p-type material, an intrinsic semiconductor, NiO, CuAlO₂, SrCu₂O₂, LaCuOS, SiO₂, and SiNₓ.

When the buffer layer 12 is formed of an intrinsic semiconductor material, a Schottky barrier may be formed when the buffer layer 12 is bonded to the ZnO based material forming the charge supply layer 13.

As described above, in the flash memory device 30 according to the current embodiment of the present invention including the charge supply layer 13 and the buffer layer 12 formed between the substrate 11 and the charge supply layer 13, a back bias voltage can be applied to the buffer layer 12. Thus a doping process for forming a source/drain region 15 is not required and the thickness of the charge supply layer 13 may be smaller than that of the flash memory device described with respect to FIG. 1.

Also, as described above, since the thickness of the charge supply layer 13 of the flash memory device can be formed sufficiently thin, the charge supply layer 13 can be formed to a thin thickness so that current can flow through the entire charge supply layer 13. Then flash memory devices can be connected in a NAND structure without the source/drain region 15, and thus the source/drain region 15 in FIG. 4 may not be needed.

Also, as described above, when the buffer layer 12 is formed between the substrate 11 and the charge supply layer 13, and the buffer layer 12 is formed of a p-type semiconductor, the buffer layer 12 and the substrate 11 are a body for forming the whole system and thus a NAND flash memory device or a NOR flash memory device can be realized using a compound semiconductor without p-type doping.

Also, as in the embodiment described with respect to FIG. 1, the flash memory device 30 does not need a single crystal substrate and thus a mutli-stack structure can be easily realized.

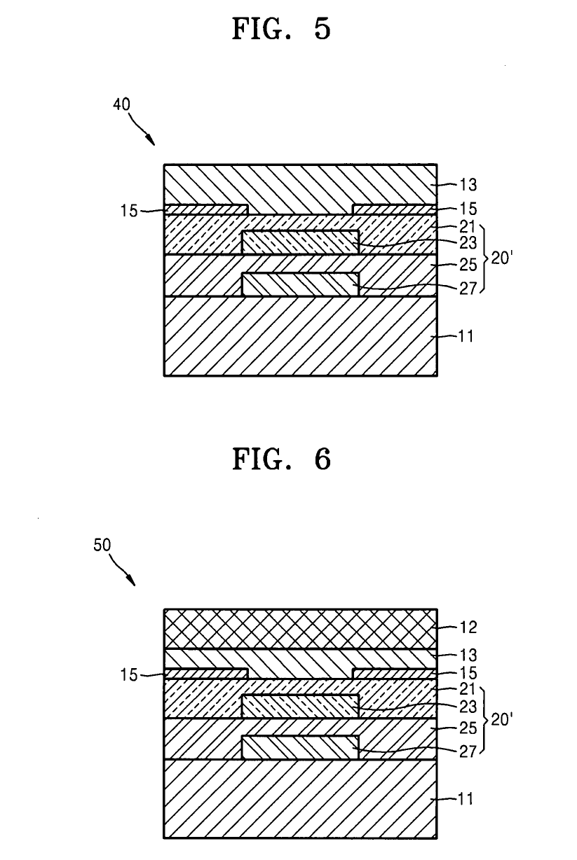

FIGS. 5 and 6 illustrate flash memory devices 40 and 50 according to other embodiments of the present invention. Here, elements of the flash memory devices 40 and 50 common to those in FIGS. 1 and 4 are denoted with the same reference numerals and the description thereof will not be repeated.

Referring to FIGS. 5 and 6, the flash memory devices 40 and 50 are bottom gate type charge trap flash (CTF) memory devices, and include a substrate 11, a gate structure 20′, and a charge supply layer 13 formed on the gate structure 20′.

The gate structure 20′ has the opposite stacking order to that of the gate structure 20 illustrated in FIG. 1. That is, the gate structure 20′ includes a control gate layer 27 formed on the substrate 11, a blocking insulating layer 25 formed to cover the control gate layer 27, a charge trap layer 23 formed to correspond to the control gate layer 27 on the blocking insulating layer 25, and a tunneling insulating layer 21 formed to cover the charge trap layer 23. The charge supply layer 13 is formed on the tunneling insulating layer 21.

The flash memory 50 device of FIG. 6 further includes a buffer layer 12 formed on the charge supply layer 13. As described above, when the buffer layer 12 is included, a back bias voltage can be applied to the buffer layer 12 instead of the charge supply layer 13. Thus the charge supply layer 13 can be formed to a smaller thickness than when the buffer layer 12 is not included such as in the flash memory device 40 of FIG. 5.

The flash memory devices of present invention may also be embodied as flash memory devices having a floating gate. In this case, the gate structure is modified as follows.

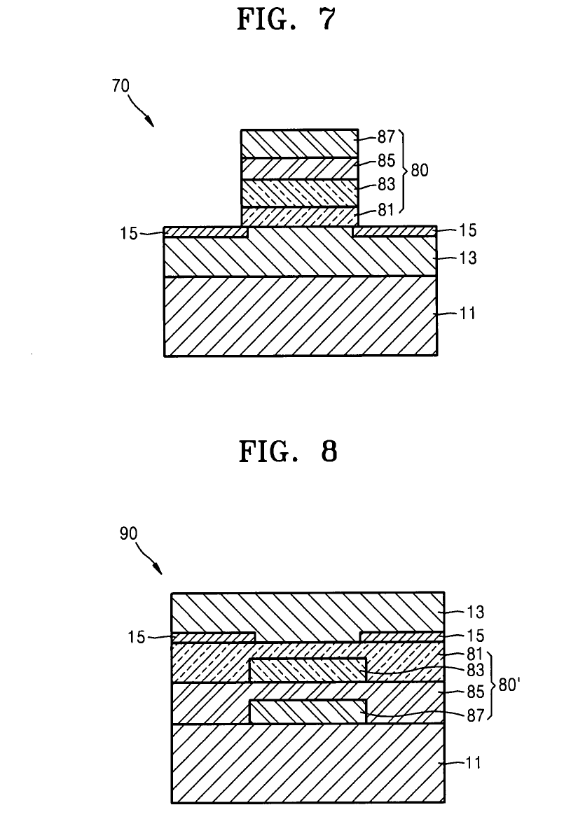

FIG. 7 illustrates a floating gate type flash memory device 70 according to another embodiment of the present invention, corresponding to the structure of FIG. 1. Here, elements of the flash memory device 70 common to those of the device illustrated in FIG. 1 is denoted with the same reference numerals and the description thereof will not be repeated.

Referring to FIG. 7, the flash memory device 70 is a bottom gate type floating gate type flash memory device and includes a substrate 11, a charge supply layer 13 formed on the substrate 11, and a gate structure 80 formed on the charge supply layer 13.

The gate structure 80 includes a tunneling insulating layer 81, a floating gate layer 83, a control gate layer 87, and an inter-gate insulating layer 85.

The tunneling insulating layer 81 may be a silicon oxide layer. The floating gate layer 83 may be a conductive polysilicon layer. The inter-gate insulating layer 85 may be a silicon oxide layer or silicon nitride layer. The control gate layer 87 may be a conductive polysilicon layer. Also, the tunneling insulating layer 81, the floating gate layer 83, the inter-gate insulating layer 85, and the control gate layer 87 may be formed of other various materials. Since the tunneling insulating layer 81, the floating gate layer 83, the inter-gate insulating layer 85, and the control gate layer 87 forming a gate structure of a floating gate type flash memory device are well known, the description thereof will be omitted.

The tunneling insulating layer 81, the floating gate layer 83, the inter-gate insulating layer 85, and the control gate layer 87 of the floating gate type flash memory device 70 respectively correspond to the tunneling insulating layer 21, the charge trap layer 23, the blocking insulating layer 25, and the control gate layer 27 of the charge trap type flash memory device described with reference to the above embodiments.

In FIG. 7, the gate structure 80 is formed as a stack gate in which the floating gate layer 83 and the control gate layer 87 are stacked to be completely interposed on each other. In the floating gate type flash memory device according to the current embodiment of the present invention, the gate structure 80 may be formed as a split gate structure in which a floating gate 83 and a control gate 87 are stacked to be partially interposed on each other. The split gate structure is well known in the field of flash memories, and thus illustration thereof will be omitted.

The floating gate type flash memory device 70 of FIG. 7 may further include a buffer layer 12 between the substrate 11 and the charge supply layer 13 like the charge trap type flash memory device illustrated in FIG. 4.

FIG. 8 is a schematic view of a floating gate type flash memory device 90 according to another embodiment of the present invention, corresponding to the device of FIG. 5. Here, elements of the flash memory device 90 common to those of the devices illustrated in FIGS. 1 and 5 are denoted with the same reference numerals and the description thereof will not be repeated.

Referring to FIG. 8, the flash memory device 90 is a bottom gate type floating gate type flash memory device and includes a substrate 11, a gate structure 80′ formed on the substrate 11, and a charge supply layer 13 formed on the gate structure 80′.

The gate structure 80′ has the opposite stack order to the gate structure 80 of FIG. 7. That is, the gate structure 80′ includes a stack in which a control gate layer 87 formed on the substrate 11, an inter-gate insulating layer 85 formed to cover the control gate layer 87, a floating gate layer 83 formed to correspond to the control gate layer 87 on the inter-gate insulating layer 85, and a tunneling insulating layer 81 formed to cover the floating gate layer 83. The charge supply layer 13 is formed on the tunneling insulating layer 81.

The flash memory device 90 of FIG. 8 may further comprises a buffer layer 12 formed on the charge supply layer 13 like the charge trap type flash memory device illustrated in FIG. 6.

As described above, the flash memory device of the charge trap type or floating gate type according to various embodiments of the present invention can be applied as a memory cell in a flash memory apparatus. When a plurality of charge trap type or floating gate type flash memory devices are connected in a NAND structure, a charge trap type or a floating gate type NAND flash memory device can be obtained. When a plurality of charge trap type or floating gate type flash memory devices are connected in a NOR structure, a charge trap type or floating gate NOR flash memory device can be obtained.

The flash memory device according to the current embodiment of the present invention may be formed of any one of a top gate type and a bottom gate type, as such a NAND or NOR flash memory device including a top gate type or bottom gate type memory cell array can be realized. Each memory cell may be a charge trap type flash memory device or a floating gate type flash memory device.

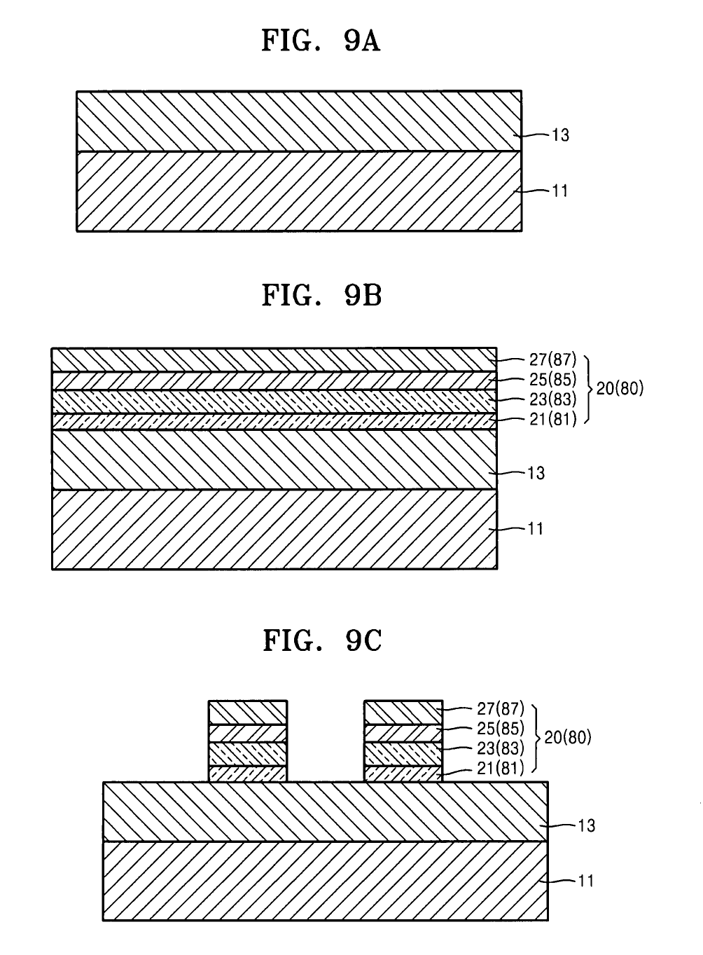

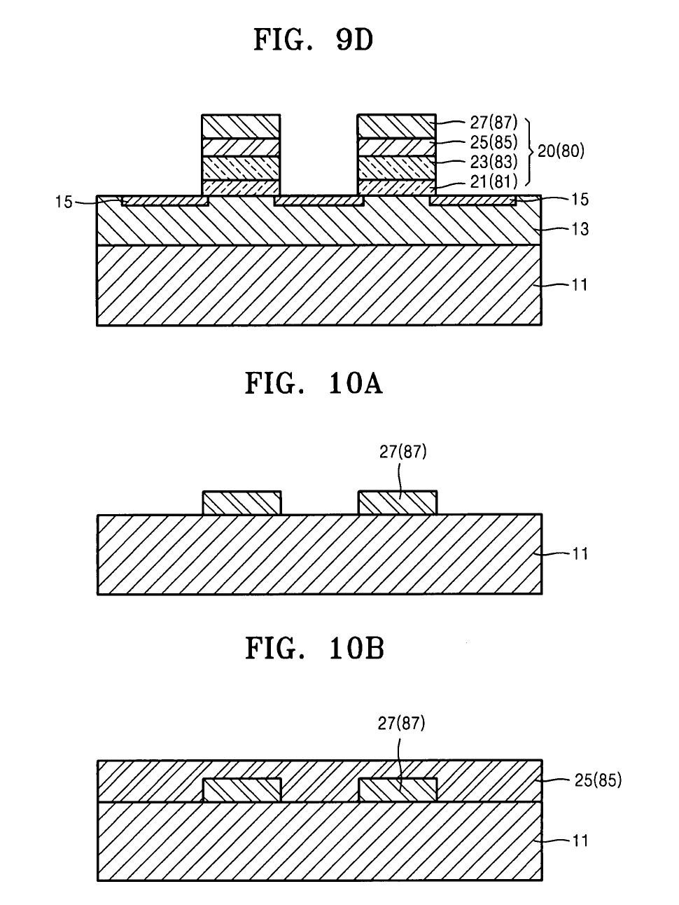

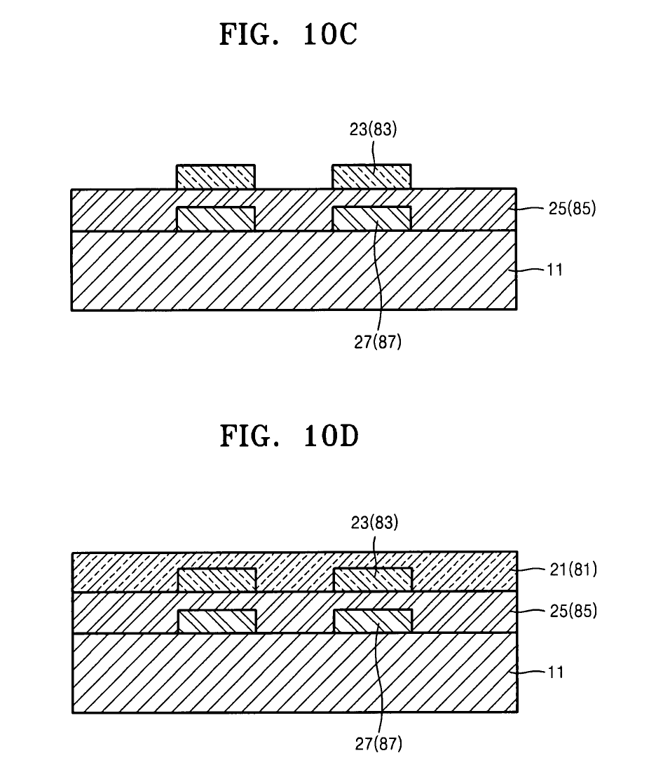

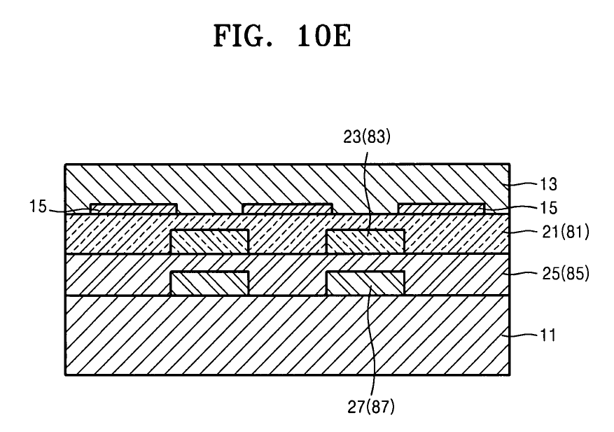

Hereinafter, a method of manufacturing the flash memory devices according to embodiments of the present invention will be described with reference to FIGS. 9A through 9D and FIGS. 10A through 10E. The charge trap type flash memory device and the floating gate type flash memory device can be formed using a similar or identical processes, and thus methods of manufacturing all types of the flash memory device are illustrated on the same drawings. Here, elements common to previous embodiments are denoted with the same reference numerals and the description thereof will not be repeated.

FIGS. 9A through 9D illustrate a method of manufacturing a top gate type flash memory device according to an embodiment of the present invention.

Referring to FIG. 9A, first, a charge supply layer 13 including a ZnO based material, for example, a material including ZnO or GaInZnO is formed on a substrate 11.

Next, referring to FIG. 9B, a gate structure 20 or 80 is formed. In the case of a charge trap type flash memory device, a tunneling insulating layer 21 is formed on the charge supply layer 13, a charge trap layer 23 is formed on the tunneling insulating layer 21, a blocking insulating layer 25 is formed on the charge trap layer 23, and a control gate layer 27 is formed on the blocking insulating layer 25. In the case of the floating gate type flash memory device, a tunneling insulating layer 81 is formed on the charge supply layer 13, and a floating gate layer 83 is formed on the tunneling insulating layer 81, and an inter-gate insulating layer 82 is formed on the floating gate layer 83, and a control gate layer 87 is formed on the inter-gate insulating layer 85.

Next, referring to FIG. 9C, a memory cell array for manufacturing a flash memory device is formed by patterning.

Next, as illustrated in FIG. 9D, a source/drain region 15 is formed in the charge supply layer 13 by a plasma processing method. The source/drain region 15 is formed to be connected to the tunneling insulating layer 21 or 81 of the gate structure 20 or 80. In FIG. 9D, the source/drain region 15 is formed such that memory cells are connected in a NAND structure.

When the charge supply layer 13 is formed to be thin such that a current can flow through the entire charge supply layer 13, the forming process of the source/drain region 15 of FIG. 9D may be omitted.

When a top gate type charge trap type or a top gate type floating gate type flash memory device is formed to further include the above described buffer layer 12, the buffer layer 12 is formed on the substrate 11 in FIG. 9A and the charge supply layer 13 is formed on the buffer layer 12.

FIGS. 10A through 10E illustrate a method of manufacturing a bottom gate type flash memory device according to an embodiment of the present invention.

First, with respect to a bottom gate type charge trap type flash memory device, as illustrated in FIG. 10A, a pattern of a control gate layer 27 is formed in each memory cell position of a charge trap type flash memory apparatus to be formed on the substrate 11. Next, as illustrated in FIG. 10B, a blocking insulating layer 25 is formed to cover the pattern of the control gate layer 27. Next, as illustrated in FIG. 10C, a pattern of a charge trap layer 23 is formed to correspond to the pattern of the control gate layer 27. Next, as illustrated in FIG. 10D, a tunneling insulating layer 21 is formed to cover the pattern of the charge trap layer 23. Next, as illustrated in FIG. 10E, a charge supply layer 13 is formed on the tunneling layer 21.

With respect to a method of manufacturing a bottom gate type floating gate type flash memory device, as illustrated in FIG. 10A, a pattern of a control gate layer 87 is formed in each memory cell position of a flash memory device to be formed on the substrate 11. Next, as illustrated in FIG. 10B, an inter-gate insulating layer 85 is formed to cover a pattern of a control gate layer 87. Next, as illustrated in FIG. 10C, a pattern of a floating gate layer 83 is formed to correspond to the pattern of the control gate layer 87 on the inter-gate insulating layer 85. Next, as illustrated in FIG. 10D, a tunneling insulating layer 81 is formed to cover the pattern of the floating gate layer 83. Next, as illustrated in FIG. 10E, a charge supply layer 13 is formed on the tunneling insulating layer 81.

The charge supply layer 13 can be formed in the following manner. A portion of the charge supply layer 13 is formed to a thickness corresponding to the thickness of the source/drain region 15, and the source/drain region 15 is formed to connect the memory cells in a NAND or NOR structure by plasma processing. Then the rest of the charge supply layer 13 is formed such that the charge supply layer 13 has a desired thickness. In FIG. 10E, the source/drain region 15 is formed such that memory cells are connected in a NAND structure.

Alternatively, when the charge supply layer 13 is formed to be sufficiently thin such that a current can flow through the entire charge supply layer 13, the charge supply layer 13 is formed to a desired thickness without forming the source/drain region 13.

Meanwhile, when the bottom gate type charge trap type or floating gate type flash memory device further includes the buffer layer 12 as illustrated in FIG. 4, the charge supply layer 13 is formed as illustrated in FIG. 10E, and then the buffer layer 12 is further formed on the charge supply layer 13.

The flash memory device as described above includes a charge supply layer formed of a ZnO based material having greater charge mobility than silicon, for example, a material including ZnO or ZnO doped with Ga and In, that is, a material including GaInZnO.

As the charge supply layer is included, additional doping process for forming a channel can be omitted, and the source/drain region can be formed without using an n-type doping process but by using other methods, for example, plasma processing, thereby simplifying the manufacturing process.

Also, the charge supply layer can be formed using a more low temperature manufacturing process than using silicon, and thus a stack structure for realizing a highly integrated memory device can be easily formed at low cost.

Also, as the additional charge supply layer is included, the flash memory device according to the present invention can be formed to be any of a bottom gate type and a top gate type.

Also, the flash memory device according to the present invention can be realized to be any of a charge trap type and a floating gate type.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A flash memory device comprising a gate structure on a substrate, the flash memory device comprising:
a charge supply layer including a ZnO based material formed between the substrate and the gate structure or formed on the gate structure.

2. The flash memory device of claim 1, wherein the charge supply layer is formed of a material including ZnO or GaInZnO.

3. The flash memory device of claim 1, wherein the charge supply layer is formed of a material including a(In₂O₃).b(Ga₂O₃).c(ZnO) (where, a, b, and c are real numbers satisfying the condition: a≧O, b≧O, c>0).

4. The flash memory device of claim 3, wherein the charge supply layer is formed of a material including a(In₂O₃).b(Ga₂O₃).c(ZnO) (where a, b, and c are real numbers satisfying the condition: a≧1, b≧1, 0<c≦1).

5. The flash memory device of claim 1, further comprising a buffer layer between the substrate and the charge supply layer.

6. The flash memory device of claim 5, wherein the buffer layer is formed to include one selected from the group consisting of a p-type semiconductor material, an intrinsic semiconductor, NiO, CuAlO₂, SrCu₂O₂, LaCuOS, SiO₂, and SiNₓ.

7. The flash memory device of claim 5, further comprising a source/drain region formed in the charge supply layer to be connected to the gate structure.

8. The flash memory device of claim 7, wherein the source/drain region is formed by plasma processing.

9. The flash memory device of claim 1, further comprising a source/drain region formed in the charge supply layer to be connected to the gate structure.

10. The flash memory device of claim 9, wherein the source/drain region is formed by plasma processing.

11. The flash memory device of claim 1, wherein the flash memory device is of a top-gate type in which the gate structure is formed on the charge supply layer, and
the gate structure includes a tunneling insulating layer, a charge trap layer, a blocking insulating layer, and a control gate layer sequentially stacked on the charge supply layer.

12. The flash memory device of claim 1, wherein the flash memory device is of a top-gate type in which the gate structure is formed on the charge supply layer, and
the gate structure includes a tunneling insulating layer, a floating gate layer, an insulating layer between gates, and a control gate layer sequentially stacked on the charge supply layer.

13. The flash memory device of claim 1, wherein the flash memory device is of a bottom gate type in which the gate structure is formed on the substrate and the charge supply layer is formed on the gate structure,
wherein the gate structure includes a control gate layer, a blocking insulating layer, a charge trap layer, and a tunneling insulating layer sequentially stacked on the substrate, and
the charge supply layer is formed on the tunneling insulating layer.

14. The flash memory device of claim 1, wherein the flash memory device is of a bottom gate type in which the gate structure is formed on the substrate and the charge supply layer is formed on the gate structure,
wherein the gate structure includes a control gate layer, a blocking insulating layer, a floating gate layer, and a tunneling insulating layer sequentially stacked on the substrate, and
the charge supply layer is formed on the tunneling insulating layer.
